(19) United States
(12) Patent Application Publication
(10) Pub. No.: US 2007/0053167 A1
(43) Pub. Date: Mar. 8, 2007

(54) Electronic circuit module and manufacturing method thereof

(75) Inventor: Jun Ueda, Yoshino-gun (JP)

Correspondence Address: NIXON & VANDERHYE, PC, 901 NORTH GLEBE ROAD, 11TH FLOOR, ARLINGTON, VA, 22203, US

(73) Assignee: Sharp Kabushiki Kaisha, Osaka (JP)

(21) Appl. No.: 11/517,402

(22) Filed: Sep. 8, 2006

(30) Foreign Application Priority Data
Sep. 8, 2005 (JP) 2005-261398

(51) Int. Cl. H05K 7/20

(52) U.S. Cl. 361/717

(57) ABSTRACT

An electronic circuit module includes (i) a semiconductor integrated circuit component which is a transistor integrated circuit formed on a semiconductor substrate, (ii) a passive element component constituting a peripheral circuit of the semiconductor integrated circuit component, and (iii) first and second circuit substrates each of which has a component mounting surface on which at least one of the semiconductor integrated circuit component and the passive element component. The respective component mounting surfaces of the first and second circuit substrate face one another. The first circuit substrate functions as one outer wall of a housing, where the electronic circuit module contacts an external circuit substrate on which the electronic circuit module is mounted. The second circuit substrate functions as the other outer wall of the housing of the module.

This Nonprovisional application claims priority under 35 U.S.C. § 119(a) on Patent Application No. 261398/2005 filed in Japan on Sep. 8, 2005, the entire contents of which are hereby incorporated by reference.

### FIELD OF THE INVENTION

The present invention relates to an electronic circuit module, and preferably relates to a high-frequency electronic circuit module for mobile equipments, which circuit module is required to be small and thin.

### BACKGROUND OF THE INVENTION

As high-frequency semiconductor components of high-frequency wireless equipments such as mobile phones, high-frequency electronic circuit modules are typically used. Such high-frequency electronic circuit modules are arranged in such a manner that, a semiconductor integrated circuit component as a functional element and passive components as peripheral circuits of the integrated circuit component are integrally mounted on a circuit substrate, in order to downsize the components, simplify the fabrication and maintenance, and standardize the components. A high-frequency electronic circuit module is typically constructed as follows: a semiconductor integrated circuit components such as a power amplifier, a high-frequency switch, and an LNA (Low Noise Amplifier) and passive components termed chip components, such as a small resistor, a capacitor, a coil are mounted on a single-layer or multi-layer circuit substrate which has a wiring pattern formed thereon and is made of low-temperature-burned glass ceramic, alumina ceramic, glass epoxy or the like.

To meet recent strong demands for downsizing and improvement in functions of mobile wireless equipments, high-frequency electronic circuit modules, which are components of the mobile wireless equipments, have also been required to have smaller sizes. For example, a high-frequency functional component must be small, for the purpose of incorporating new high-frequency wireless data communication functions, such as wireless LAN (Local Area Network) and Bluetooth®, into mobile PCs and mobile phones, as additional functions. To achieve this, Japanese Laid-Open Patent Application No. 2004-14807 (published on Jan. 15, 2004) and Japanese Laid-Open Patent Application No. 2003-100937 (published on Apr. 4, 2003) disclose methods of downsizing an electronic circuit module by packaging semiconductor integrated circuit components and passive components in a three-dimensional manner so as to increase the packaging density. Such methods have already be in practical use.

FIG. 7 is a cross sectional structural drawing of a module, according to a method disclosed by Japanese Laid-Open Patent Application No. 2004-14807 (published on Jan. 15, 2004). Note that since this figure is cited from the Japanese application, numbers and signs in the same are left as they are. The module forming method of the Japanese application is arranged as follows: a circuit substrate 7 has two main surfaces, a recessed portion 41 is formed on one main surface 702 where an electrode for the connection with an external substrate is provided, a semiconductor integrated circuit component 20 is provided in the recessed portion 41, and a passive component 61 is provided on the other main surface 701. With this, the method makes it possible to package components in three dimension, using both surfaces of the circuit substrate 7. As a result, the module is downsized because components and circuits are provided also on the back side of the semiconductor integrated circuit component 20. Moreover, since the semiconductor integrated circuit component 20 is provided in the recessed portion, it is possible to restrain the height of the module.

FIG. 8 shows a cross sectional structural drawing of a module according to another method disclosed by Japanese Laid-Open Patent Application No. 2003-100937 (published on Apr. 4, 2003). Note that since this figure is cited from the Japanese application, numbers and signs in the same are left as they are. The module forming method of the Japanese application is arranged as follows: a recessed portion 30 is formed on a first circuit substrate 10, a semiconductor integrated circuit component 100 is provided in the recessed portion 30, and a second circuit substrate 20 on which a passive component 110 is provided is placed on the first circuit substrate 10. With this, the method makes it possible to package the components in three dimension. Since components and circuits can be provided over the semiconductor integrated circuit component 100, the module is downsized.

The module disclosed in Japanese Laid-Open Patent Application No. 2004-14807 (published on Jan. 15, 2004) is arranged in such a manner that, on the first main surface (top surface) of a circuit substrate, passive components such as a matching circuit and a bias circuit are provided, whereas semiconductor integrated circuit components such as a power amplifier IC and a switch IC are provided in a recessed portion on the second main surface (bottom surface) of the circuit substrate. In such a module, the semiconductor integrated circuit components that are heat sources are suspended from the bottom of the recessed portion. Therefore, the heat generated by the semiconductor integrated circuit components is transmitted from the bottom face of the recessed portion, where the components are mounted, to a heat sink of an external substrate, via a radiating path (an electrode 43 in FIG. 7) which extends from the bottom surface of the recessed portion to the back side of the circuit substrate, where contact with the external substrate is made. Since the radiating path is lengthy as above and the path must be provided so as to bypass the wiring pattern in the circuit substrate, it is basically difficult to provide a sufficiently thick path. With a narrow path, the heat radiation property is severely deteriorated.

With poor heat radiation property, the temperature of a semiconductor integrated circuit component in operation easily increases and the range of operable temperatures decreases. The reliability of the module is hampered. Furthermore, the structure of the substrate is complicated and special manufacturing process and equipments are required, thereby increasing manufacturing costs.

The module disclosed by Japanese Laid-Open Patent Application No. 2003-100937 (published on April 4) is arranged in such a manner that a semiconductor integrated circuit component such as a power amplifier IC and a switch IC is provided on a first circuit substrate which directly contacts an external substrate, whereas passive components such as a chip resistor and a chip capacitor which constitute a matching circuit, a bias circuit, or the like are provided on a second substrate, and the second circuit substrate is mounted on the first substrate, with both of the component mounting surfaces facing upward. In such a module, heat generated by the semiconductor integrated circuit components can easily be transmitted to a heat sink of the external substrate, by a thick heat radiating path which penetrates the substrate and is directly below the component mounting surface of the first circuit substrate. On account of this arrangement, a high heat radiation property is achieved. However, since two circuit substrates are stacked, the height of the module cannot be restrained.

Each of the modules disclosed by Japanese Laid-Open Patent Application No. 2004-14807 (published on Jan. 15, 2004) and Japanese Laid-Open Patent Application No. 2003-100937 (published on Apr. 4, 2003) is arranged such that passive components are mounted on a circuit substrate surface which is the top surface of the module. Therefore, some sort of covering means is required for protecting the mounted components and keeping the contour of the module to have a predetermined shape. The top surface of the module requires a plane whose size is sufficient to mark the production number and perform vacuum contact for handling the module. In particular, the covering means is indispensable for small modules. The covering means is typically (i) a metal case by which shielding effect is also obtained or (ii) sealing resin such as epoxy resin made by printing or transfer molding using a molding die. Such processes increase the manufacturing costs of the module, because a die and a resin material for the metal case and the sealing resin are required. This problem is particularly conspicuous in the arrangement disclosed by Japanese Laid-Open Patent Application No. 2003-100937 (published on Apr. 4, 2003).

### SUMMARY OF THE INVENTION

The present invention was done to solve the above-identified problem. The present invention provides an electronic circuit module which is small, thin, manufactured at low cost, and has a good heat radiation property, and a manufacturing method of the electronic circuit module.

To achieve the objective above, the electronic circuit module of the present invention includes: a semiconductor integrated circuit component which is a transistor integrated circuit formed on a semiconductor substrate; a passive element component which constitutes a peripheral circuit of the semiconductor integrated circuit component; and first and second circuit substrates which have respective component mounting surfaces, at least one of the semiconductor integrated circuit component and the passive element component being provided on each of the component mounting surfaces, the component mounting surfaces of the first and second circuit substrates facing each other, the first circuit substrate functioning as one outer wall of a housing of the electronic circuit module, at said one outer wall the electronic circuit module contacting an external substrate on which the electronic circuit module is mounted, and the second circuit substrate functioning as another outer wall of the housing of the module.

According to this arrangement, the back of the component mounting surface of the second circuit substrate functions as the outer wall at the top surface of the module, so that the outline of the module is formed. It is therefore unnecessary to additionally provide covering means. The outer wall in this case indicates a member constituting the outline of the module. The substrate still functions as the outer wall, even if a conductive film or a protective film is formed on the outer wall.

To achieve the objective above, a method of manufacturing the electronic circuit module of the present invention includes the steps of: combining the first circuit substrate with the second circuit substrate with the component mounting surfaces facing one another, after components are mounted on the respective first and second circuit substrates; and integrating the first circuit substrate with the second circuit substrate by joining, using solder or anisotropic conductive resin, (i) an electrode of one of the first and second circuit substrates facing each other, which electrode is on an end of the joining wall, with (ii) an electrode of the other one of the first and second circuit substrates.

According to this manufacturing method, semiconductor circuit components and passive components of the electronic circuit module are mounted by the same processes and equipments as conventional single circuit substrate mounting.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1 is a cross sectional structural drawing of an electronic circuit module of Embodiment 1 of the present invention.

FIG. 2 is an oblique perspective view of the electronic circuit module of FIG. 1.

FIG. 3(a) is a circuit diagram of a high-frequency power amplifier, which is used for illustrating the electronic circuit module of the present invention.

FIG. 3(b) is a circuit diagram of a high-frequency switch, which is used for illustrating the electronic circuit module of the present invention.

FIG. 3(c) is a circuit diagram in which the power amplifier of FIG. 3(a) is combined, as a module, with the high-frequency switch of FIG. 3(b), and functions thereof are integrated. This figure is used for illustrating the electronic circuit module of the present invention.

FIG. 4(a) shows an assembly process of the electronic circuit module of FIG. 1, and is a cross section in which components are mounted on a first circuit substrate.

FIG. 4(b) shows an assembly process of the electronic circuit module of FIG. 1, and is a cross section in which components are mounted on a second circuit substrate.

FIG. 4(c) shows an assembly process of the electronic circuit module of FIG. 1, and is a cross section in which the component mounting surface of the first circuit substrate 1 of FIG. 4(a) faces the component mounting surface of the second circuit substrate 2.

FIG. 4(d) shows an assembly process of the electronic circuit module of FIG. 1, and is a cross section in which the two circuit substrates of FIG. 4(c) are mechanically joined with one another.

FIG. 5(a) is a cross sectional structural drawing for illustrating Embodiment 2 of the present invention, and is a cross section in which components are mounted on a first circuit substrate.

FIG. 5(b) is a cross sectional structural drawing for illustrating Embodiment 2 of the present invention, and is a cross section in which components are mounted on a second circuit substrate.

FIG. 5(c) is a cross sectional structural drawing for illustrating Embodiment 2 of the present invention, and is a cross section showing a module after being assembled.

FIG. 6 is an oblique perspective view for illustrating Embodiment 3 of the present invention.

FIG. 7 is a cross sectional structural drawing for illustrating an electronic circuit module of conventional art.

FIG. 8 is a cross sectional structural drawing for illustrating another background art.

### DESCRIPTION OF THE EMBODIMENTS

[Embodiment 1]

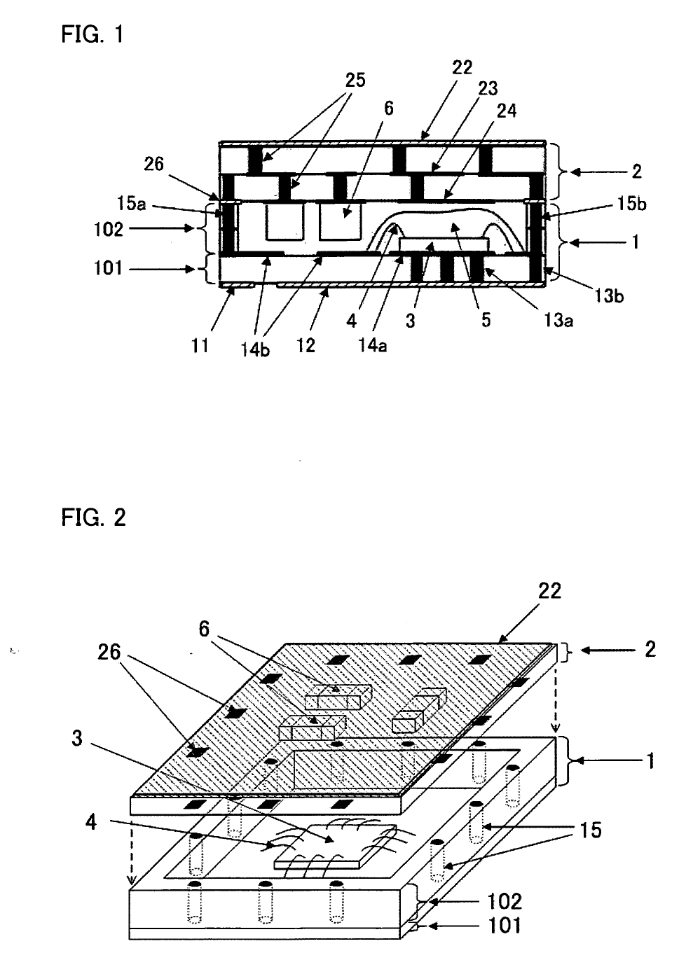

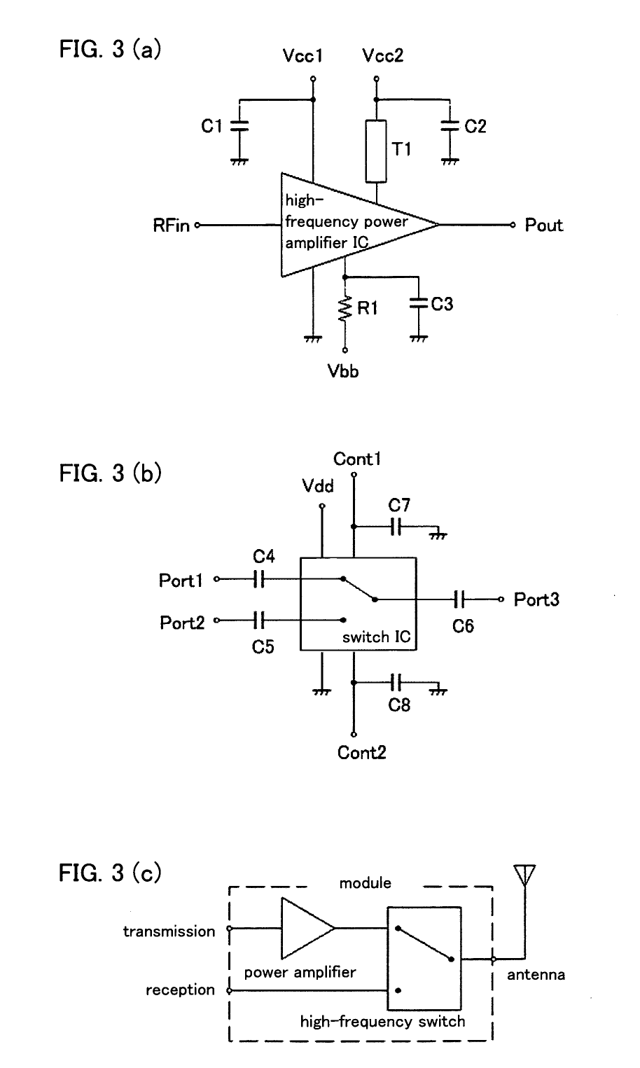

FIG. 1 is a cross sectional structural drawing of an electronic circuit module of Embodiment 1 of the present invention. FIG. 2 is an oblique perspective view showing how the present embodiment is arranged. FIGS. 3(a), 3(b), and 3(c) are circuit examples for illustrating functions of the electronic circuit module of the present embodiment. For simplicity, a first circuit substrate 1 is separated from a second circuit substrate 2 in the oblique perspective view of FIG. 2. Also, some of the components are not illustrated in the figure for the sake of simplicity.

The circuit shown in FIG. 3(a) is a high-frequency power amplifier which includes, as shown in the circuit diagram, (i) a high-frequency power amplifier IC which is a semiconductor integrated circuit and (ii) peripheral circuits of power supply terminals Vcc1, Vcc2, and Vbb. The high-frequency power amplifier is used for obtaining a high-power signal required for wireless transmission. In this amplifier, the power of a signal supplied to an input terminal RFin is amplified and the signal is, as a transmission signal, supplied to an output terminal Pout. The high-frequency power amplifier IC typically generates a large quantity of heat, because it deals with a large electric power. The high-frequency power amplifier IC includes amplifier elements such as a bipolar transistor and FET. To allow these circuits to properly operate at high frequencies, the power supply terminals are connected with capacitors and a coil for adjusting load impedance and cutting out high frequencies. In the circuit shown in FIG. 3(a), capacitors C1 and C3 are connected to the power supply terminals Vcc1 and Vbb, respectively, whereas a capacitor C2 and a transmission line functioning as a coil are connected to the power supply terminal Vcc2. For adjusting a bias potential, the Vbb terminal is connected to a resistor R1.

The circuit shown in FIG. 3(b) is a high-frequency switch circuit which includes (i) a switch IC that is a semiconductor integrated circuit and (ii) peripheral circuits of the switch IC. In response to signals supplied to control terminals Cont1 and Cont2, the high-frequency switch causes a high-frequency terminal Port3 to be connected to either a terminal Port1 or a terminal Port2. The switch IC typically adopts an FET as a switch element. The high-frequency terminals Port1 to Port3 require capacitors C4, C5, and C6 for cutting out DC, whereas the control terminals Cont1 and Cont2 require bypass capacitors C7 and C8.

In the above-described example, peripheral circuit elements are externally connected to the high-frequency semiconductor integrated circuit. This is because, (i) if the peripheral circuit elements are built in the semiconductor integrated circuit, those elements occupy a large area in the integrated circuit, thereby causing cost increase, and (ii) since externally-connected elements are adjustable, good performance is achieved. However, circuits with a lot of externally-connected elements have limited uses. This problem is solved by an electronic circuit module in which a semiconductor integrated circuit component is integrated with passive components as peripheral circuits of the semiconductor integrated circuits, and these components are mounted on a circuit substrate.

The high-frequency switch circuit shown in FIG. 3(b) is used for switching between transmission and reception in an antenna section of a wireless equipment. The high-frequency switch circuit may be arranged in such a manner that a high-frequency Port 3 is connected to the antenna, and a transmission output signal amplified by the power amplifier shown in FIG. 3(a) is supplied to a high-frequency terminal Port 1 or a high-frequency terminal Port 2. In case where the circuit is arranged in this way, as shown in the block diagram in FIG. 3(c), the power amplifier in FIG. 3(a) is integrated with the high-frequency switch in FIG. 3(b) so that the functions of these components are integrated in a single module.

The present embodiment takes the high-frequency power amplifier shown in FIG. 3(a) as an example. The present invention, however, is not limited to this, because the present invention can be applied to various circuits which have been shown in the examples above. Moreover, the present invention is not limited to high-frequency circuits, because, integration of functions by combining peripheral circuit elements can be achieved not only in high-frequency electronic circuit modules but also in electronic circuit modules in general.

The electronic circuit module shown in FIGS. 1 and 2 includes the aforesaid high-frequency power amplifier IC and its peripheral circuits. In the electronic circuit module, a first circuit substrate 1 and a second circuit substrate 2, on both of which components are mounted, are provided with the component mounting surfaces facing one another. The high-frequency power amplifier 3, which is a semiconductor integrated circuit, is provided on the first circuit substrate 1. A capacitor, which is a peripheral circuit component, is mounted as a chip capacitor 6, on the second circuit substrate 2. In this way, the semiconductor integrated circuit component, which generates heat, is mounted on the first circuit substrate 1 which is in contact with the external substrate, and hence the heat radiating path to the heat sink of the external substrate is short. It is therefore possible to obtain a good radiation property. In the present embodiment, furthermore, the circuit pattern is designed in consideration of the positions of the components, in order to prevent the mounted components of the first circuit substrate 1 from interfering with the mounted components of the second circuit substrate 2, and vice versa. With this circuit pattern, it is possible to restrain the height of the module.

The following will describe the electronic circuit module in reference to FIG. 1.

The first circuit substrate 1 uses, as a base material, low-temperature-burned glass ceramic. Alternatively, the base material of the circuit substrate 1 may be alumina ceramic. A substrate made of ceramic has sufficient strength and good flatness, and the size and dielectric constant thereof do not change so much on account of temperature. Ceramic is therefore suitable for a material of a circuit substrate on which a semiconductor integrated circuit component which generates heat is mounted.

On the component mounting surface of a main circuit substrate 101 of the first circuit substrate 1, the following patterns are formed: an area electrode pattern 14a for die-bonding a high-frequency power amplifier IC chip; and an electrode pattern 14b where an electrode and transmission line pattern which are connected with a signal terminal and a power supply terminal of the IC are formed. On the other hand, on the back of the component mounting surface, the following components are provided: a terminal 11 which is connected to either (i) a wire by which an electric power or an RFin signal from the external substrate is supplied to the module or (ii) a wire by which a Pout signal is supplied from the module to the external substrate; and a ground terminal 12 which is connected to a ground potential and functions as the heat sink of the external substrate. The electrode patterns 14a and 14b on the component mounting surface are connected with the terminals 11 and 12 provided on the back side, through via holes 13a and 13b penetrating the main circuit substrate 101 of the first circuit substrate 1. In particular, the via holes 13a functioning as the heat radiating path are formed directly below the area electrode pattern 14a where the high-frequency power amplifier IC 3 is mounted. With this, the heat radiation of the ground terminal 12 formed on the back side is ensured.

Formed on the periphery of the first circuit substrate 1 is a joining wall 102. The joining wall 102 functions as framing means having an electric path, and includes via holes 15a and 15b. (It is noted that the via holes 15a and 15b shown in FIG. 1 are identical with one another, and those holes are collectively termed via holes 15 in other figures.) Each of the via holes 15a and 15b is a through hole in which a conductor is formed. These via holes 15a and 15b penetrate the joining wall 102 from the top surface to the bottom surface, so as to form an electric path by which electric conduction is achieved. Bottom-side terminals of the via holes 15a and 15b are connected to the electrode pattern 14b formed on the main circuit substrate 101 of the first circuit substrate 1. On the other hand, the top-side terminals of the via holes 15a and 15b are exposed on the top surface of the joining wall 102, and function as connecting electrodes by which an electric circuit on the first circuit substrate 1 is connected to the second circuit substrate 2. Furthermore, the via holes 15b are connected with the ground terminal 12, via the via holes 13b which penetrate the main circuit substrate 101 of the first circuit substrate 1. With this arrangement, the ground potential is supplied to the circuit substrate 2.

The joining wall 102 arranged as above can be formed in such a manner that, for example, a base material which has been molded as a frame surrounding the component mounting region is processed, stacked on the main circuit substrate 101, and burned. The joining wall 102 is frame means which is used for securing a space where components such as the high-frequency power amplifier IC 3 and the chip capacitor 6 are provided. Taking into account of this, the height of the joining wall 102 is determined in consideration of the heights of those components in the space.

The high-frequency power amplifier IC 3 is dye-bonded with the area electrode pattern 14a, using conductive resin such as silver paste. Also, the high-frequency power amplifier IC 3 is electrically connected with the electrode pattern 14b of the circuit substrate, by means of gold wires 4. For the protection from damages during the manufacturing process and for the improvement in weather resistance, the high-frequency power amplifier IC 3 and the gold wires 4 are coated with potting resin 5.

On the second circuit substrate 2 of the present embodiment, no components generating heat are mounted. On this account, the second circuit substrate 2 is a multi-layered wired glass epoxy substrate. The second circuit substrate 2, however, is not necessarily arranged in this way. For example, the second circuit substrate 2 may be a multi-layer substrate made of ceramic of which the first circuit substrate 1 is made. In case where the second circuit substrate 2 is made of such a material, passive elements such as a capacitor and a coil can be formed in a layer inside the substrate, so that the number of components mounted on the substrate is reduced to up to zero. This arrangement is suitable for further reducing the size and thickness of the module.

The circuit pattern of the second circuit substrate 2 is constituted by an electrode pattern 24 formed on the component mounting surface, an electrode pattern 23 formed on a layer inside the substrate, and a ground metal 22 formed on the back of the component mounting surface. The metals on the respective layers are connected with one another by via holes 25.

The electrode pattern 24 on the component mounting surface of the second circuit substrate 2 is provided with a solder pad where a chip component is soldered. On this solder pad, the chip capacitor 6 is mounted. On the component mounting surface of the second circuit substrate 2, connecting electrodes 26 are provided so as to face the respective via holes 15a and 15b which penetrate the joining wall 102 of the first circuit substrate 1. Two circuit substrates are electrically connected with each other by these connecting electrodes 26.

The ground metal 22 is connected to the ground potential of the external substrate, via the via holes 25 penetrating the second circuit substrate 2, the via holes 15b penetrating the joining wall 102 of the first circuit substrate 1, and the via holes 13b penetrating the main circuit substrate 101 of the first circuit substrate 1. The ground metal 22 covers almost the entirety of the back of the component mounting surface. The ground metal 22 functions as a ground plane of the transmission line of circuits provided on the second circuit substrate, and also functions as a shield by which the circuits in the electronic circuit module are electromagnetically shielded from the outside.

As described above, the electronic circuit module of the present embodiment is small in size, because the circuits are provided in a three-dimensional manner thanks to two circuit substrates. Furthermore, since the component mounting surfaces of the first and second circuit substrates face each other, all of the mounted components are sandwiched between two circuit substrates. On this account, the back of the component mounting surface of the second circuit substrate functions as the outer wall of the module, because the back of the component mounting surface faces the external substrate when the electronic circuit module is mounted on the external substrate, i.e. the back of the component mounting surface is on the upper side of FIG. 1. According to this arrangement, apart from two circuit substrates, no additional means is required to cover the mounted components. On the back of the component mounting surface of the second circuit substrate, the ground metal connected to the ground potential is provided. Cap means for shielding is therefore unnecessary, and reduction in thickness and costs is achieved.

The semiconductor integrated circuit components which generate heat are mounted on the first circuit substrate which is in contact with the external substrate. With this, good heat radiation property is ensured. Also, as shown in FIG. 1, the components mounted on the first and second circuit substrates are laid out in such a manner as not to interfere with one another, in consideration of the sizes and positions of the components. The electronic circuit module is therefore thinner than conventional ones.

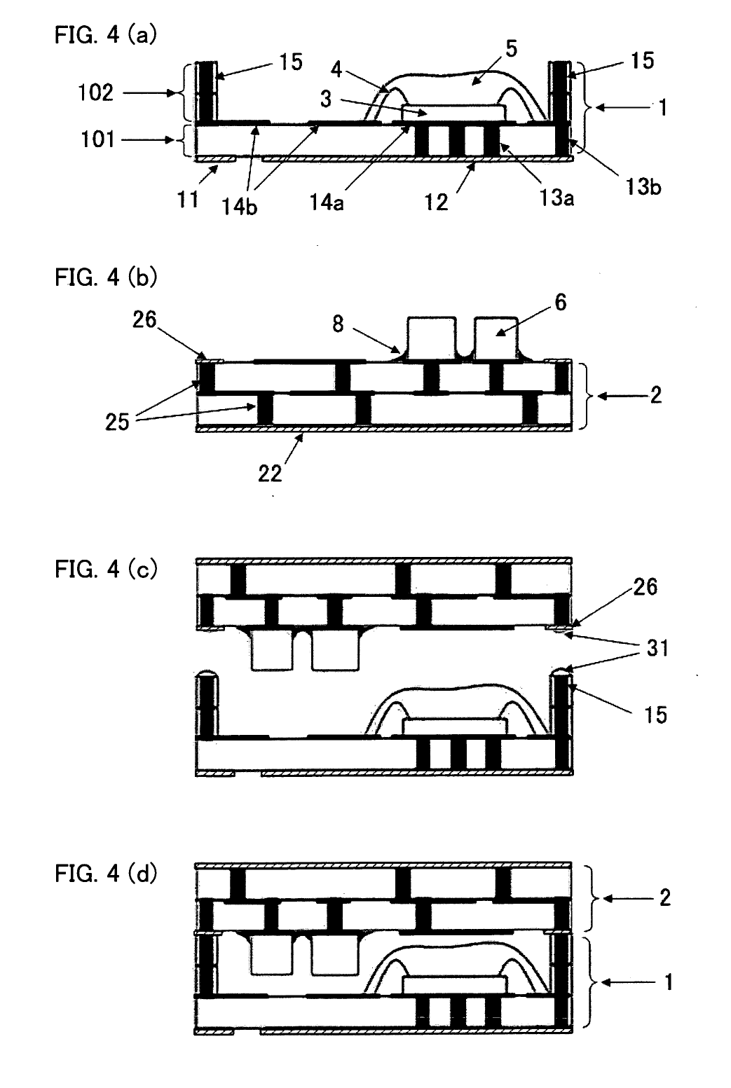

The following will briefly describe a manufacturing method of the electronic circuit module of the present invention. FIGS. 4(a)-4(d) are cross sections for illustrating the manufacturing steps.

FIG. 4(a) shows in what manner the components are mounted on the first circuit substrate. On the first circuit substrate 1, a joining wall 102 which is penetrated by via holes 15 is formed. The joining wall 102 is formed by providing a base material to surround the component mounting region, and burning the base material. In the present embodiment, the first circuit substrate 1 is constituted by three layers made of a low-temperature-burned glass ceramic base material and includes a main circuit substrate 101 on which a circuit pattern is formed. The upper two layers of the first circuit substrate 1 are the joining wall 102, and this joining wall 102 forms a space between the first and second substrates 1 and 2 and supports these substrates. To secure a space where the components are mounted, the joining wall 102 must be higher in height than the mounted components. In the present embodiment, the joining wall is 500 μm in thickness and constituted by two base material layers each of which is 250μm thick.

On the first circuit substrate 1, a high-frequency power amplifier IC 3 is dye-bonded. By gold wires 4, an electrode pattern 14b on the substrate is wire-bonded with the terminals of the IC. Thereafter, the high-frequency power amplifier IC 3 and the gold wires 4 are coated with potting resin 5 such as epoxy resin, for the protection from damages during the manufacturing process and for the improvement in weather resistance. If the IC is sufficiently weather-resistant and no damage is caused in the manufacturing process, the coating by the potting resin may be omitted.

FIG. 4(b) shows in what manner the components are mounted on the second circuit substrate. On the second circuit substrate 2, a chip capacitor 6 which is a passive component is mounted. To a solder pad by which the chip component is connected, solder paste has been applied in advance by screen printing or the like. The component is mounted at a predetermined position, is subjected to reflowing in an oven, and is soldered. To protect the solder-joint part, an underfill material 8 is applied and cured. Potting resin may be applied as a protective material. The protective material may be unnecessary if the solder-joint part is sufficiently reliable.

The components are mounted on the first and second circuit substrates 1 and 2, in the same manner as components mounted on a typical single substrate. No special facilities and processes are required for mounting the components.

As shown in FIG. 4(c), after the components are mounted on the first and second circuit substrates, the first circuit substrate 1 and the second substrate 2 are combined with one another with the respective component mounting surfaces facing one another. On the component mounting surface of the second circuit substrate 2, connecting electrodes 26 are provided so as to face the respective via holes 15 penetrating the joining wall 102. In a combining step, the connecting electrodes 26 are connected with the electrodes of the via holes 15, which electrodes are exposed at the upper end of the joining wall 102.

The combining step is carried out as follows.

Solder paste 31 is applied to (i) the electrodes of the via holes 15, which electrodes are exposed at the upper end of the joining wall 102 of the first circuit substrate 1, and (ii) the connecting electrode 26 provided on the second circuit substrate 2. Then the second circuit substrate 2 is aligned with the first circuit substrate 1, and placed thereon. While being tentatively joined with one another by the solder paste, the electrodes are put into a reflowing furnace which has a temperature profile in conformity to the melting condition of the solder paste 31. In the reflowing furnace, the solder in the solder paste 31 is melted so that the electrodes are soldered. By this soldering, the via holes 15 are electrically connected with the connecting electrodes 26 facing the respective via holes 15, so that the circuit is formed. Moreover, two circuit substrates are mechanically joined with one another so that the module is formed (FIG. 4(d)). In this case, it is preferable to use solder paste which has a lower melting point than the solder paste used for mounting the chip component on the second circuit substrate 2. However, the melting points of these solder pastes may be identical with one another, because, on account of the surface tension of the solder, the chip component does not fall away even if the solder is melted again.

The combining step may be alternatively arranged as follows: an anisotropic conductive adhesive is applied to or a film-shaped anisotropic conductive adhesive is pasted on the entirety of the upper end of the joining wall 102 where the electrodes of the via holes 15 are exposed; the second circuit substrate 2 is aligned with the first circuit substrate 1 and placed thereon; and the circuit substrate are joined with one another by curing the adhesive at temperatures of 100-200° C. and under pressure. Because of conductive particles in the anisotropic conductive adhesive, the via holes are electrically connected with the corresponding connecting electrodes 26 so that the circuit is formed. Also, two circuit substrates are mechanically joined with one another so that the module is formed.

In the present embodiment, the joining wall 102 is formed on the periphery of the first circuit substrate 1. The joining wall 102, however, is not necessarily provided on the first circuit substrate side. The joining wall 102 may be formed on the second circuit substrate 2 side. In such a case, the connecting electrodes 26 are formed on the first circuit substrate 1. Also, joining walls may be formed in the respective substrates in such a manner as to have a predetermined thickness in combination. In this case, the electrodes of the via holes exposed on the ends of the both joining walls are aligned with one another and connected with one another.

[Embodiment 2]

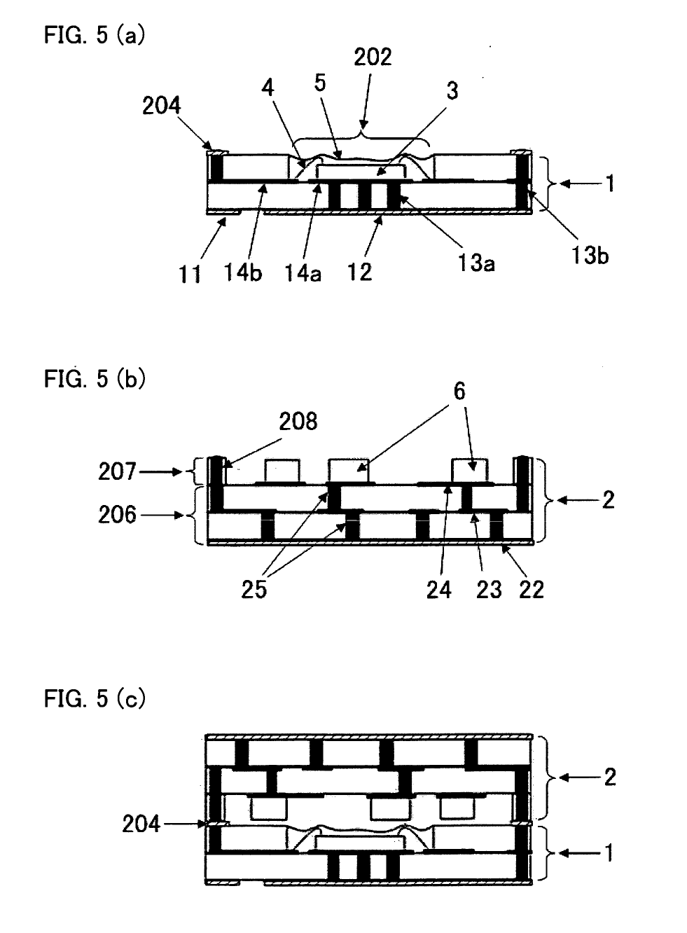

FIGS. 5(a)-5(c) are cross sectional structural drawings for illustrating Embodiment 2 of the present invention. A mounted circuit in the present embodiment is identical with the high-frequency power amplifier circuit shown in FIG. 3(a). FIG. 5(a) shows in what manner components are mounted on a first circuit substrate. FIG. 5(b) shows in what manner components are mounted on a second circuit substrate. FIG. 5 (c) shows a module after being constructed. By the way, members having the same functions as those described in Embodiment 1 are given the same numbers, so that the descriptions are simplified.

Being similar to Embodiment 1, a first circuit substrate 1 on which a high-frequency power amplifier IC 3 which is a semiconductor integrated circuit is mounted is fixed with a second circuit substrate 2 on which a chip capacitor 6 which is a passive component, with the component mounting surfaces of the respective circuit substrates facing each other. In the present embodiment, the first circuit substrate 1 has an IC-mounting area which is a cavity. The high-frequency power amplifier IC 3 is mounted in such a manner as to be housed in the cavity 202. With this arrangement, the height of the module is restrained irrespective of the positions of the components on the second circuit substrate 2 which faces the first circuit substrate 1.

The first circuit substrate 1 is a multi-layer substrate made of low-temperature-burned glass ceramic. Desired wiring patterns and electrodes are formed by (i) electrode patterns (e.g. electrodes 11, 12, 14a, 14b and 204 in FIG. 5(a)) formed on the both surfaces of the substrate and an inner layer of the substrate and (ii) via holes 13a and 13b which connect the electrode patterns on the layers. The component mounting surface is provided with the cavity 202 where the high-frequency power amplifier IC 3 is mounted. On the bottom of the cavity, the following electrode patterns are provided: an area electrode pattern 14a for dye-bonding, which is sufficiently heat resistant on account of the via hole 13a; and an electrode pattern 14b which is connected, by wires, to the terminals of the IC. On the outer periphery of the component mounting surface, connecting electrodes 204 are provided. The connecting electrodes 204 electrically connect the first circuit substrate 1 with the second circuit substrate 2, when these circuit substrates are joined with one another. On the back of the component mounting surface, the following components are provided: a terminal 11 which is corrected to either a wire for supplying power and an RFin signal from the external substrate to the module or a wire for supplying a Pout signal from the module to the external substrate; and a ground terminal 12 which is connected to a ground potential and functions as the heat sink of the external substrate.

The high-frequency power amplifier IC 3 is dye-bonded with the area electrode on the bottom of the cavity 202, and connected, by gold wires 4, to the electrodes of the circuit substrate. To protect the high-frequency power amplifier IC 3 and the gold wires 4, the cavity 202 is filled with potting resin 5. In the present embodiment, the cavity 202 is filled with the potting resin 5 in order to protect the high-frequency power amplifier IC 3 and the gold wires 4. Alternatively, the cavity may be sealed by using a metal cap.

The second circuit substrate 2 is a multi-layer wired glass epoxy resin substrate in which a circuit pattern around a power source terminal of the high-frequency power amplifier IC 3 is formed. The circuit pattern includes an electrode pattern 24 formed on the component mounting surface, an electrode pattern 23 formed on the layer inside the substrate, and a ground metal 22 formed on the back of the component mounting surface. The metals on the respective layers are connected with one another by via holes 25. The electrode pattern 24 of the component mounting surface is provided with a solder pad which is used for soldering a chip component. On the solder pad, a chip capacitor 6 which is a passive component is mounted.

Formed on the periphery of the component mounting surface is a joining wall 207 penetrated by via holes 208. At the upper end of the joining wall, the via holes 208 are exposed and electrodes are formed. The via holes 208 are formed so as to correspond to the connecting electrodes 204 provided on the first circuit substrate 1. When the second circuit substrate is joined with the first circuit substrate, the via holes 208 are electrically connected with the connecting electrode 204. The joining wall 207 is formed in the following manner: a base made of the same material as the circuit substrate is shaped into a frame surrounding the component mounting region; the via holes 208 are made through the base; and the base is stacked on the circuit substrate 206 which is the main layer.

Being similar to Embodiment 1, the back of the component mounting surface of the second circuit substrate 2 is almost entirely covered with the ground metal 22. The ground metal 22 functions as a ground plane of the transmission line on the second circuit substrate 2. Also, the ground metal 22 effectively functions as a shield by which the circuits in the electronic circuit module are electromagnetically shielded from the outside.

The first circuit substrate 1 is joined with the second circuit substrate 2, in the same manner as Embodiment 1.

As described above, The electronic circuit module of the present embodiment is small in size, because circuits are arranged in a three-dimensional manner by using two circuit substrates. Also, since the component mounting surfaces of the first and second circuit substrates face each other, all of the mounted components are sandwiched between two circuit substrates. With this arrangement, all of the mounted components are sandwiched between two circuit substrates. On this account, the back of the component mounting surface of the second circuit substrate functions as the outer wall of the module, because the back of the component mounting surface faces the external substrate when the electronic circuit module is mounted on the external substrate, i.e. the back of the component mounting surface is on the upper side of FIG. 5(c). On the back of the component mounting surface of the second circuit substrate, the ground metal connected to the ground potential is provided. On account of this, no covering means is required for shielding, and hence the reduction in thickness and costs is achieved. Also, a semiconductor integrated circuit component which generates heat is mounted on the first circuit substrate which is in touch with the external substrate. With this, good heat radiation property is ensured. Furthermore, the first circuit substrate has an IC-mounting area which is a cavity. An integrated circuit component is mounted in such a manner as to be housed in the cavity. With this arrangement, the height of the module is restrained irrespective of the positions of the components on the second circuit substrate which faces the first circuit substrate.

[Embodiment 3]

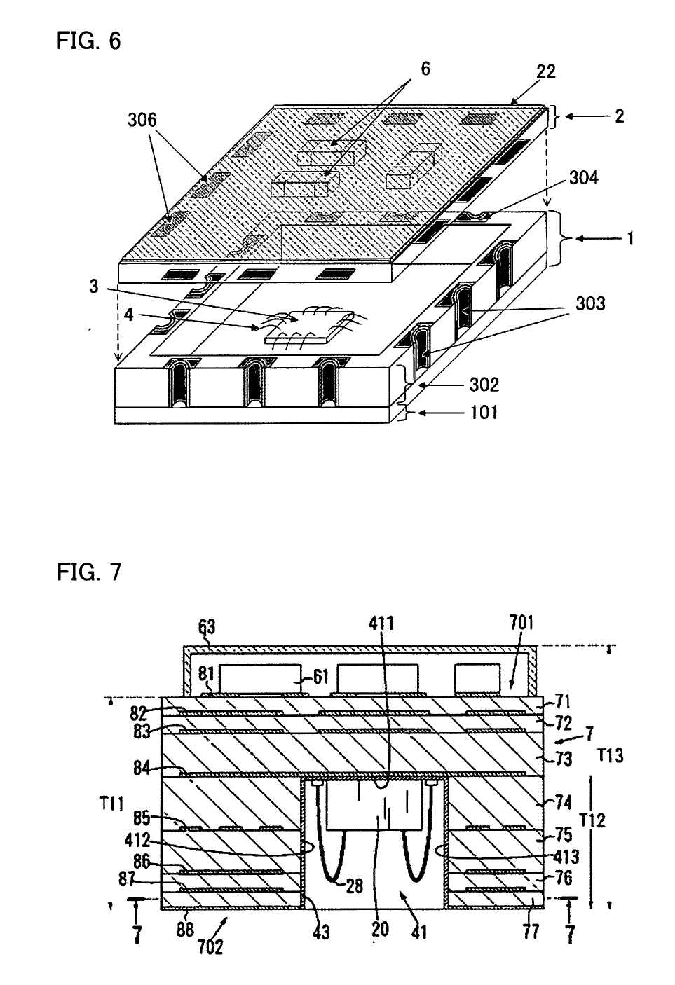

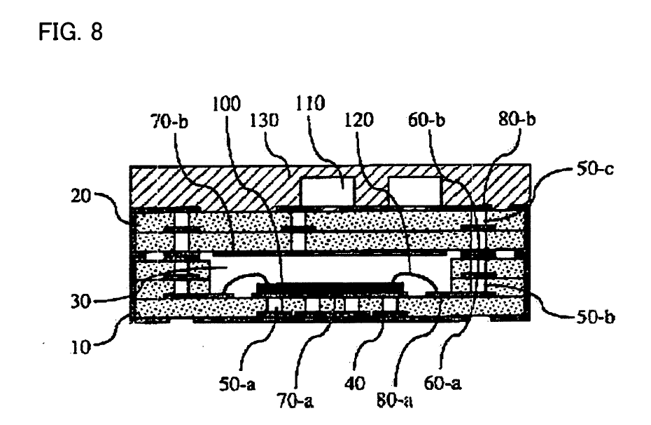

FIG. 6 is an oblique perspective view of an electronic circuit module, which is used for describing Embodiment 3 of the present invention. In the present embodiment, castellations are formed as electric paths through the joining wall, in place of via holes. Apart from this, Embodiment 3 is substantially identical with Embodiment 1. Therefore members having the same functions as those described in Embodiment 1 are given the same numbers, so that the descriptions are simplified. In the oblique perspective view, the first circuit substrate 1 is separated from the second circuit substrate 2, in order to simplify the figure. In the completed module, however, two substrates are joined with each other. Also, as in the case of FIG. 2 in Embodiment 1, some of the components are not illustrated in FIG. 6 for simplicity.

An electronic circuit module includes: a first circuit substrate 1 on which a high-frequency power amplifier IC 3 which is a semiconductor integrated circuit is mounted; and a second circuit substrate 2 on which a chip capacitor 6 which is a passive component is mounted. The component mounting surface of the first circuit substrate 1 faces the component mounting surface of the second circuit substrate 2.

In the present embodiment, a joining wall 302 is arranged such that castellations 303 are formed around the periphery of the first circuit substrate 1. In each of the castellations 303, a conductive film is formed inside a semicircle-shaped groove on the side surface of the joining wall 302. The castellations 303 function as electric paths between the upper end to the bottom end of the joining wall 303. The side surface of each of the castellations 303 is connected to the circuit pattern formed on the main circuit substrate 101 of the first circuit substrate 1. The side surface of each of the castellations 303 on the upper end is connected to a first connecting electrode 304 formed on the upper surface of the joining wall 302.

The joining wall 302 is made of the same base material as the main circuit substrate 101 of the first circuit substrate 1, and formed in such a manner that low-temperature-burned glass ceramic substrates or alumina ceramic substrates are laminated. The castellations on the side surfaces of the joining wall are formed as below.

Circuit substrates are typically formed in one large base material sheet, and each of the circuit substrates is obtained by dividing the base material sheet. Therefore the outer peripheral side surfaces of the joining wall 302 which is at the periphery of the circuit substrate is the cross-section surfaces of the circuit substrate formed by the division. The castellations are formed in such a manner that through-holes are formed along the division lines by punching or the like, and conductive films mainly made of silver or copper is formed inside the through-holes. When the base material sheet is divided into the circuit substrates, the through-holes are divided in two so that the castellations are formed. Since the electrode area in each castellation is larger than the electrode area of a via hole, castellations are preferable in cases such as a large current is supplied and low-loss transmission is required.

The second circuit substrate 2 of the present embodiment is identical with that of Embodiment 1. The component mounting surface is provided with second connecting electrodes 206 which are positioned to correspond the first connecting electrode 304 and are connected to the circuit pattern on the second circuit substrate 2. When the second circuit substrate 2 is joined with the first circuit substrate 1, two circuit substrates are electrically connected with one another by the aforesaid connecting electrodes. The first and second circuit substrate 1 and 2 are joined with each other in the same manner as Embodiment 1.

In the present embodiment, the joining wall having the castellations may be formed in the second circuit substrate, instead of the first circuit substrate. Also, joining walls may be formed in the respective substrates in such a manner as to have a predetermined thickness in combination.

As described above, according to the present embodiment, a small, thin, and low-cost electronic circuit module is obtained by arranging the component mounting surfaces of the first and second circuit substrates to face with one another, as in the cases of Embodiments 1 and 2. Since the castellations are used as electric connection means between the first and second circuit substrates, low-loss connection is achieved. On this account, the electronic circuit module can be used for devices consuming a large amount of power (e.g. 500 mW), such as mobile phones. Moreover, the joining wall having the castellations may be further penetrated by via holes. This makes it possible to deal with multiple signals.

The electronic circuit module of the present invention includes: a first circuit substrate on which components are mounted; and a second circuit substrate on which components are mounted, a component mounting surface of the first circuit substrate faces a component mounting surface of the second circuit substrate, and the first circuit substrate functions as an outer wall of the electronic circuit module, on the side of contacting with an external circuit substrate on which the electronic circuit module is mounted, whereas the second circuit substrate functions as the other outer wall of the module.

According to this arrangement, the back of the component mounting surface of the second circuit substrate functions as the outer wall at the top surface of the module, so that the outline of the module is formed. It is therefore unnecessary to additionally provide covering means. The outer wall in this case indicates a member constituting the outline of the module. The substrate still functions as the outer wall, even if a conductive film or a protective film is formed on the outer wall.

The back of the component mounting surface of the second circuit substrate is covered with a conductive film connected to a ground potential. With this, a shielding effect similar to that of a metal cap is obtained.

The semiconductor integrated component is mounted on the first circuit substrate. With this, heat generated by the semiconductor integrated circuit component is radiated to the external substrate, by a short heat radiation path.

The electronic circuit module formed in such a manner that, after mounting components on the first and second circuit substrates, these circuit substrates are joined with one another with the component mounting surfaces of the first and second circuit substrates facing each other. According to this manufacturing method, semiconductor circuit components and passive components are mounted by the same processes and equipments as conventional single circuit substrate mounting.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. An electronic circuit module comprising:
a semiconductor integrated circuit component which is a transistor integrated circuit formed on a semiconductor substrate;
a passive element component which constitutes a peripheral circuit of the semiconductor integrated circuit component; and
first and second circuit substrates which have respective component mounting surfaces, at least one of the semiconductor integrated circuit component and the passive element component being provided on each of the component mounting surfaces,
the component mounting surfaces of the first and second circuit substrates facing each other,
the first circuit substrate functioning as one outer wall of a housing of the electronic circuit module, at said one outer wall the electronic circuit module contacting an external substrate on which the electronic circuit module is mounted, and
the second circuit substrate functioning as another outer wall of the housing of the module.

2. The electronic circuit module as defined in claim 1, further comprising a frame section where an electric path is formed to electrically connect the first circuit substrate with the second circuit substrate,
the first and second circuit substrates being joined with one another in such a manner that the component mounting surfaces of the first and second circuit substrates face each other with the frame section being interposed therebetween.

3. The electronic circuit module as defined in claim 2,
wherein, the frame section is a joining wall which includes a via hole and is provided on at least one of the component mounting surfaces of the first and second circuit substrates.

4. The electronic circuit module as defined in claim 2,
wherein, the frame section is a joining wall which includes a castellation and is provided on at least one of the component mounting surfaces of the first and second circuit substrates.

5. The electronic circuit module as defined in claim 1,
wherein, a conductive film connected with a ground potential is provided on the back of the component mounting surface of the second circuit substrate.

6. The electronic circuit module as defined in claim 1,
wherein, the semiconductor integrated circuit component is mounted on the first circuit substrate.

7. The electronic circuit module as defined in claim 1,
wherein, a component on the first circuit substrate and a component on the second circuit substrate are laid out in such a manner as not to interfere with one another, when the first circuit substrate and the second circuit substrate are arranged so as to face one another.

8. The electronic circuit module as defined in claim 1,
wherein, at least a part of the semiconductor integrated circuit component and at least a part of the passive component are covered with resin.

9. A method of manufacturing an electronic circuit module which includes:
a semiconductor integrated circuit component which is a transistor integrated circuit formed on a semiconductor substrate;
a passive element component which constitutes a peripheral circuit of the semiconductor integrated circuit component; and
first and second circuit substrates which have respective component mounting surfaces, at least one of the semiconductor integrated circuit component and the passive element component being provided on each of the component mounting surfaces,
the component mounting surfaces of the first and second circuit substrates facing each other,
the electronic circuit module further including a frame section where an electric path is formed to electrically connect the first circuit substrate with the second circuit substrate,
the first and second circuit substrates being joined with one another in such a manner that the component mounting surfaces of the first and second circuit substrates face each other with the frame section being interposed therebetween,
the frame section being a joining wall which includes a via hole and is provided on at least one of the component mounting surfaces of the first and second circuit substrates,
the first circuit substrate functioning as one outer wall of a housing of the electronic circuit module, at said one outer wall the electronic circuit module contacting an external substrate on which the electronic circuit module is mounted, whereas the second circuit substrate functioning as another outer wall of the housing of the module,
the method comprising the steps of:
combining the first circuit substrate with the second circuit substrate with the component mounting surfaces facing one another, after components are mounted on the respective first and second circuit substrates; and
integrating the first circuit substrate with the second circuit substrate by joining, using solder or anisotropic conductive resin, (i) an electrode of one of the first and second circuit substrates facing each other, which electrode is on an end of the joining wall, with (ii) an electrode of the other one of the first and second circuit substrates.

10. A method of manufacturing an electronic circuit module which includes:
a semiconductor integrated circuit component which is a transistor integrated circuit formed on a semiconductor substrate;
a passive element component which constitutes a peripheral circuit of the semiconductor integrated circuit component; and
first and second circuit substrates which have respective component mounting surfaces, at least one of the semiconductor integrated circuit component and the passive element component being provided on each of the component mounting surfaces,
the component mounting surfaces of the first and second circuit substrates facing each other,
the electronic circuit module further including a frame section where an electric path is formed to electrically connect the first circuit substrate with the second circuit substrate,
the first and second circuit substrates being joined with one another in such a manner that the component mounting surfaces of the first and second circuit substrates face each other with the frame section being interposed therebetween,
the frame section being a joining wall which includes a castellation and is provided on at least one of the component mounting surfaces of the first and second circuit substrates,
the first circuit substrate functioning as one outer wall of a housing of the electronic circuit module, at said one outer wall the electronic circuit module contacting an external substrate on which the electronic circuit module is mounted, whereas the second circuit substrate functioning as another outer wall of the housing of the module,
the method comprising the steps of:
combining the first circuit substrate with the second circuit substrate with the component mounting surfaces facing one another, after components are mounted on the respective first and second circuit substrates; and
integrating the first circuit substrate with the second circuit substrate by joining, using solder or anisotropic conductive resin, (i) an electrode of one of the first and second circuit substrates facing each other, which electrode is on an end of the joining wall, with (ii) an electrode of the other one of the first and second circuit substrates.
